(19) United States
(12) Patent Application Publication
(10) Pub. No.: US 2008/0054480 A1
(43) Pub. Date: Mar. 6, 2008

(54) Semiconductor device and fabricating method thereof

(75) Inventor: Cheon Man Shim, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/895,338

(22) Filed: Aug. 24, 2007

(30) Foreign Application Priority Data
Aug. 29, 2006 (KR) 10-2006-0082439

(51) Int. Cl. H01L 23/48; H01L 21/20

(52) U.S. Cl. 257/773; 438/666; 257/E23.01; 257/E21.09

(57) ABSTRACT

A semiconductor device includes a lower layer having an uneven region on a top surface, a dielectric barrier layer disposed on the lower layer and having an even top surface, and an interlayer dielectric layer disposed on the dielectric barrier layer and having an even top surface.

### CROSS-REFERENCE TO RELATED APPLICATIONS

The present invention claims priority under 35 U.S.C. 119 and 35 U.S.C. 365 to Korean Patent Application No. 10-2006-0082439 (filed on Aug. 29, 2006), which is hereby incorporated by reference in its entirety.

### BACKGROUND

Embodiments of the invention relate to a semiconductor device and a fabricating method thereof.

Generally, semiconductor devices of 130 nm or less use copper (Cu) metal as conductive metallization and low dielectric constant (k) material as an intermetal or interlayer dielectric material. In such semiconductor devices, an interlayer dielectric (ILD) is deposited by a chemical vapor deposition (CVD) process or a plasma enhanced chemical vapor deposition (PECVD) process.

Due to a chemical mechanical polishing (CMP) process, regions of the polished material may be depressed by slurry or foreign particles, a phenomenon sometimes known as “dishing.” In this case, when a material is deposited by a PECVD process or a CVD process, the material is conformally deposited on an uneven surface (e.g., the depressed portion).

If a portion of a substrate is excessively depressed, a metal line material (e.g., Al or Cu) may remain on a layer above the depressed portion during a subsequent process of forming a metal line. Such a metal residue may cause a short circuit.

### SUMMARY

Embodiments of the invention provide a semiconductor device, which can improve one or more device characteristics and device reliability by preventing metal residue during a process of forming a metal line, and a fabricating method thereof.

An embodiment of the invention provides a semiconductor device including: a lower layer having an uneven region on a top surface; a dielectric barrier layer on the lower layer and having an even top surface; and an interlayer dielectric layer on the dielectric barrier layer and having an even top surface.

A further embodiment of the invention provides a semiconductor device including: a lower layer having an uneven region on a top surface; a dielectric barrier layer on the lower layer and having an uneven top surface corresponding to the uneven region of the lower layer; and an interlayer dielectric layer on the dielectric barrier layer and having an even top surface.

An embodiment provides a method for fabricating a semiconductor device. The method includes: forming a lower layer having an uneven region on a top surface; forming a dielectric barrier layer having an even top surface on the lower layer by a coating process; and forming an interlayer dielectric layer having an even top surface on the dielectric barrier layer.

### BRIEF DESCRIPTION OF THE DRAWINGS

FIGS. 1A-B are cross-sectional views of stacked structures of semiconductor devices according to embodiments of the invention.

FIGS. 2A-B are cross-sectional views of stacked structures of semiconductor devices according to other embodiments of the invention.

### DETAILED DESCRIPTION OF THE EMBODIMENTS

Reference will now be made in detail to the embodiments of the present disclosure, examples of which are illustrated in the accompanying drawings.

In the following description, it will be understood that when a layer is referred to as being ‘on/above’ another layer or substrate, it can be directly on the another layer or substrate, or intervening layers may also be present. Further, it will be understood that when a layer is referred to as being ‘under/below’ another layer, it can be directly under the another layer, and one or more intervening layers may also be present. In addition, it will also be understood that when a layer is referred to as being ‘between’ two layers, it can be the only layer between the two layers, or one or more intervening layers may also be present.

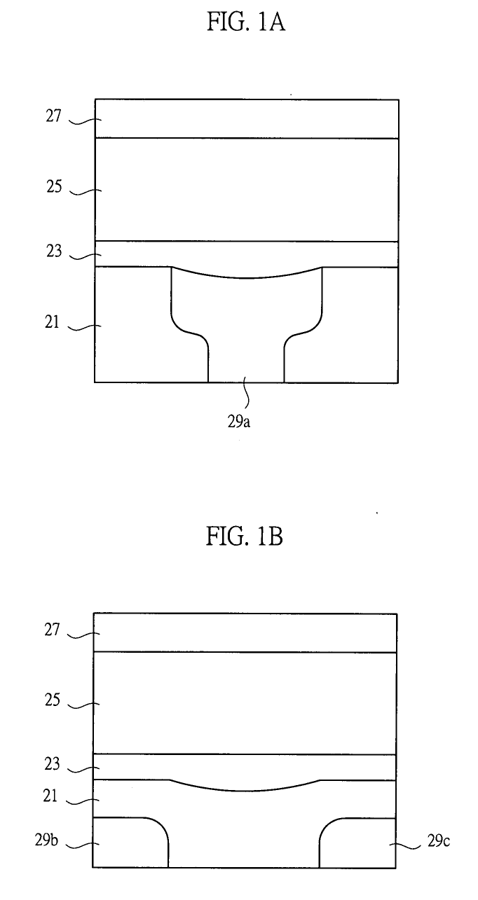

FIGS. 1A-B are cross-sectional views of stacked structures of a semiconductor device according to embodiments of the invention.

Referring to FIGS. 1A-B, the semiconductor devices include a lower layer 21, a dielectric barrier layer 23, an interlayer dielectric (ILD) layer 25, and a capping layer 27. In the device of FIG. 1A, the lower layer 21 includes one or more dielectric layers, and a metal layer 29a (e.g., comprising copper metallization) is in a “dual damascene” type trench-and-via pattern in the lower layer 21. In the device of FIG. 1B, the lower layer 21 also includes one or more dielectric layers, deposited onto metal lines 29b-c (e.g., comprising aluminum metallization) that have been formed using photolithography. A method for fabricating the semiconductor device having such a stacked structure will be described below.

An uneven region is formed in a top surface of the lower layer 21. The uneven region may be formed by a planarization process, for example, a CMP process. As shown in FIG. 1A, a metal line layer 29a may be formed in the lower layer 21. The uneven region formed in the metal line layer 29a may be a top surface of a region where the metal line is formed, such as a trench in which copper metal has been deposited (e.g., by electroplating or electroless plating). Also, as shown in FIG. 1B, the uneven region formed in the lower layer 21 may be a top surface of a region where no metal line is formed, such as an interlayer dielectric (ILD) or intermetal dielectric (IMD) layer comprising one or more doped or undoped oxides (e.g., an undoped silicate glass [USG] such as a plasma silane layer or a TEOS-based layer, a silicon-rich oxide having a ratio of silicon to oxygen atoms of from 1:1.5 to 1:1.95, or a silicate glass doped with fluorine [FSG] or boron and/or phosphorous [BSG, PSG or BPSG]) deposited over metal lines 29b-c having a relatively wide inter-line spacing or distance therebetween.

Then, and referring to both FIGS. 1A and 1B, a dielectric barrier layer 23 having an even top surface is formed on the lower layer 21. The dielectric barrier layer 23 may be formed by a coating process. Therefore, the top surface of the dielectric barrier layer 23 can be evenly formed. Examples of the coating process may include a spin coating process or a deposition-and-reflow process. Further, the dielectric barrier layer 23 may be formed of a material having a dielectric constant (k) of less than 3. The dielectric barrier layer 23 may comprise an organic bottom anti-reflective coating (BARC), a polyimide, a silicon oxide or oxynitride formed from a spin-on-glass formulation, etc.

An ILD or IMD layer 25 having an even top surface is formed on the dielectric barrier layer 23. Since the surface of the dielectric barrier layer 23 is already in the even state, the ILD layer 25 can be formed by a coating process or a deposition process. In the case of using the coating process, the top surface of the ILD layer 25 can be evenly formed. In the case of using the deposition process, since the dielectric barrier layer 23 under the ILD layer 25 has a relatively even top surface, the top surface of the ILD layer 25 can be evenly formed. The ILD/IMD layer 25 may comprise one or more of the materials described above for lower layer 21.

In this embodiment, a capping layer 27 having an even top surface may be further formed on the ILD layer 25. The capping layer 27 can be formed by a coating process or a deposition process. Examples of the coating process may include a spin coating process. Examples of the capping layer 27 can include silicon nitride, a plasma silane (e.g., SiO₂ formed by plasma-assisted chemical vapor deposition from silane [SiH4] and an oxygen source gas such as dioxygen and/or ozone, having a relatively high hardness as compared to other oxides such as a TEOS-based oxide).

The fabricating method according to this embodiment can provide the layer having the even top surface. Hence, it is possible to fundamentally prevent a metal residue (e.g., Cu or Al) from being formed in such “dishing” areas (e.g., by subsequent blanket deposition of a metal, as in the embodiment of FIG. 1B) or above such “dishing” areas (e.g., if the depression is replicated or propagated in successively deposited layers, as in the embodiment of FIG. 1A) during a subsequent process of forming a metal line.

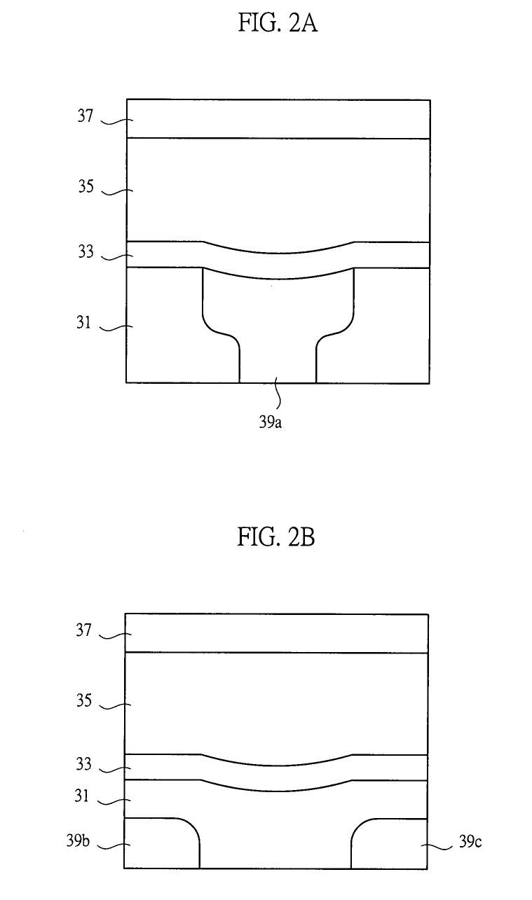

FIGS. 2A-B are cross-sectional views of a stacked structure of semiconductor devices according to other embodiments.

Referring to FIGS. 2A-B, the semiconductor devices include a lower layer 31, a dielectric barrier layer 33, an ILD layer 35, and a capping layer 37. Similar to FIGS. 1A-B, in the device of FIG. 2A, the lower layer 31 includes one or more dielectric layers and a metal layer 39a (e.g., comprising copper metallization) in a “dual damascene” type pattern. In the device of FIG. 2B, the lower layer 31 also includes one or more dielectric layers, deposited onto metal lines 39b-c (e.g., comprising aluminum metallization) that have been formed using photolithography. A method for fabricating the semiconductor devices having such a stacked structure will be described below.

An uneven region is formed in a top surface of the lower layer 31, either in metal layer 39a (FIG. 2A) or in a dielectric layer deposited over metal lines 39b-c having a relatively wide inter-line spacing. The uneven region may be formed by a planarization process, for example, a CMP process. A metal line layer (e.g., 39a as in FIG. 2A or 39b-c as in FIG. 2B) may be formed in or under the lower layer 31. The uneven region formed in the lower layer 31 may be a top surface of a region where the metal line 39a is formed (FIG. 2A). Alternatively, the uneven region formed in the lower layer 31 may be a top surface of a region over which no metal line is formed (e.g., in a relatively widely spaced region between Al lines 39b and 39c, as shown in FIG. 2B and similar to the embodiment shown in FIG. 1B).

A dielectric barrier layer 33 is formed on the lower layer 31, generally by a conformal deposition process (e.g., chemical vapor deposition [CVD], which may be plasma enhanced [PE-CVD] or high density plasma assisted [HDP-CVD], or which may be performed at low pressure [LP-CVD], subatmospheric pressure [SA-CVD] or atmospheric pressure [AP-CVD]). The dielectric barrier layer 33 has an uneven top surface corresponding to and/or generally following the uneven region of the lower layer 31.

The dielectric barrier layer 33 may be formed by a conformal deposition process. Thus, the uneven region may be formed in the top surface of the dielectric barrier layer 33. The uneven region of the dielectric barrier layer 33 is formed at a location corresponding to the uneven region of the lower layer 31. The dielectric barrier layer 33 may comprise a material having a dielectric constant (k) of less than 3, and may be selected from the CVD-depositable materials mentioned herein for dielectric materials, notably silicon nitride, silicon rich oxide, silicon oxides (doped or undoped), and silicon oxynitrides (although formed by a CVD technique, rather than a spin-coating technique).

An ILD layer 35 having an even top surface is formed on the dielectric barrier layer 33. The ILD layer 35 may be formed by a coating process, similar to layer 23 of the embodiments of FIGS. 1A-B. Thus, a top surface of the ILD layer 35 may be evenly formed. Examples of the coating process may include a spin coating process and a deposition-and-reflow process. Examples of the materials suitable for ILD/IMD layer 35 include those described for layer 23 of the embodiments of FIGS. 1A-B.

In this embodiment, a capping layer 37 having an even top surface may be further formed on the ILD layer 35. The capping layer 37 can be formed by a coating process or a (conformal) deposition process. Examples of the coating process may include a spin coating process, and examples of the materials suitable for capping layer 37 include those described for capping layer 27 of the embodiments of FIGS. 1A-B.

The fabricating method according to the above embodiments can provide an upper (capping) dielectric layer having an even (substantially horizontal and/or substantially planar) top surface. Hence, it is possible to fundamentally prevent a metal residue (e.g., Cu, Al, Ta or Ti [the letter two metals being conductive adhesive materials for Cu and/or Al metallization) from being formed during a subsequent process of forming a metal line.

By performing the coating process, the uneven region depressed by dishing, erosion, or digging resulting from a preceding planarization process can be effectively removed prior to the formation of a metal for the line. This is significantly different from a related art gap-filling process.

As described above, the semiconductor device and the fabricating method thereof according to the embodiments can prevent the metal residue (e.g., Cu, Al, Ti or Ta) from being formed in a depression during the process of forming the metal line, thereby improving the characteristics and reliability of the semiconductor device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a lower layer having an uneven region on a top surface;
a dielectric barrier layer on the lower layer and having an even top surface; and
an interlayer dielectric layer on the dielectric barrier layer and having an even top surface.

2. The semiconductor device according to claim 1, wherein the lower layer comprises a metal line layer.

3. The semiconductor device according to claim 2, wherein the uneven region of the lower layer comprises a region where there is no metal line.

4. The semiconductor device according to claim 1, further comprising a capping layer on the interlayer dielectric layer and having an even top surface.

5. The semiconductor device according to claim 1, wherein the dielectric barrier layer comprises a material having a dielectric constant (k) of less than 3.

6. A semiconductor device, comprising:
a lower layer having an uneven region on a top surface;
a dielectric barrier layer on the lower layer and having an uneven top surface corresponding to the uneven region of the lower layer; and
an interlayer dielectric layer on the dielectric barrier layer and having an even top surface.

7. The semiconductor device according to claim 6, wherein the lower layer comprises a metal line layer.

8. The semiconductor device according to claim 7, wherein the uneven region of the lower layer comprises a region where there is no metal line.

9. The semiconductor device according to claim 6, further comprising a capping layer on the interlayer dielectric layer and having an even top surface.

10. The semiconductor device according to claim 6, wherein the dielectric barrier layer comprises a material having a dielectric constant of less than 3.

11. A method for fabricating a semiconductor device, the method comprising:
forming a lower layer having an uneven region on a top surface;
forming a dielectric barrier layer having an even top surface on the lower layer by a coating process; and
forming an interlayer dielectric layer having an even top surface on the dielectric barrier layer.

12. The method according to claim 11, wherein forming the lower layer comprises forming a metal line layer, wherein the uneven region of the lower layer comprises a region where no metal line is formed.

13. The method according to claim 11, further comprising forming a capping layer having an even top surface on the interlayer dielectric layer.

14. The method according to claim 11, wherein the dielectric layer comprises a material having a dielectric constant of less than 3.

15. The method according to claim 11, wherein the uneven region is formed by a chemical mechanical polishing (CMP) process.

16. The method according to claim 11, wherein the interlayer dielectric layer is formed by a coating process or a deposition process.
